(19) United States
(12) Patent Application Publication
(10) Pub. No.: US 2014/0249777 A1
(43) Pub. Date: Sep. 4, 2014

(54) FAULT DETECTING SYSTEM AND FAULT DETECTING METHOD

(71) Applicant: Azbil Corporation, Tokyo (JP)

(72) Inventor: Masato TANAKA, Tokyo (JP)

(73) Assignee: AZBIL CORPORATION, Tokyo (JP)

(21) Appl. No.: 14/196,467

(22) Filed: Mar. 4, 2014

(30) Foreign Application Priority Data
Mar. 4, 2013 (JP) 2013-041428

(51) Int. Cl. H01L 21/66

(52) U.S. Cl. CPC H01L 22/10
USPC 702/183

(57) ABSTRACT

A fault detecting system includes a representative value storing portion that stores, as a representative value, a combination of a maximum value for a state quantity rate-of-change and a state quantity when the state quantity rate-of-change reaches the maximum value, a rate-of-change calculating portion that calculates the state quantity rate-of-change based on state quantity data acquired by a data acquiring portion, and a representative value updating portion that updates representative values stored in the representative value storing portion, to a most recent state quantity rate-of-change calculated by the rate-of-change calculating portion and a most recent state quantity that has been acquired by the data acquiring portion, when the absolute value of the most recent state quantity rate-of-change that has been calculated by the rate-of-change calculating portion is larger than the absolute value of the maximum value for the state quantity rate-of-change that is stored in the representative value storing portion.

### CROSS REFERENCE TO RELATED APPLICATION

This application claims priority under 35 U.S.C. §119 to Japanese Patent Application No. 2013-041428, filed on Mar. 4, 2013, the entire content of which being hereby incorporated herein by reference.

### FIELD OF TECHNOLOGY

The present invention relates to a fault detecting system and a fault detecting method able to use process volumes as input data to detect faults in sensors and actuators, and able to predict faults before they occur.

### BACKGROUND

In semiconductor manufacturing equipment, equipment engineering systems (EES) have reached the point of moving into the practical application stage. An EES is a system that is able to improve equipment reliability and productivity through using data to check whether or not semiconductor manufacturing equipment is functioning properly. The main purposes of an EES are to perform fault detection (FD) and fault prediction (FP) on the equipment itself. See, for example, Japan Electronics and Information Technology Industries Association, “Handbook for Checking the Performance of Equipment Functions on the Equipment Level (Sōchi reberu de no sōchi kinō no seinō kakunin ni kansuru kaisetsu-sho)”, Mar. 23, 2005.

In FD/FP, a hierarchical approach is taken on the equipment control level, the module level, the subsystem-level, and the I/O device level. FD/FP on the equipment control level is FD/FP that performs monitoring/detection of whether or not the equipment functions are operating within the tolerance range of the equipment specification, based on process conditions that have been designated by a host or an operator. FD/FP on the module level is FD/FP that performs monitoring/detection of whether or not the processing is being performed according to the specification values by a module that is structured with devices or subsystems. FD/FP on the subsystem level is FD/FP that performs monitoring/detection as to whether or not complex systems, constituting a plurality of devices, such as those that perform feedback control, are operating stably based on a variety of parameter settings. FD/FP on the I/O device level is FD/FP that performs monitoring/detection on whether or not the sensors and actuators that structure a device are operating stably according to the design values. In this way, on the I/O device level, the subjects are sensors and actuators.

When it comes to FD/FP for actuators, it can be said that sequence control operations that are based on (0, 1) bit stream data (actuator data) in particular are at the stage of practical application.

On the other hand, when it comes to FD/FP for sensors, the data of interest it are process volumes, such as temperatures, pressures, flow rates, and the like. For these data, it would be irrational to attempt to store all data on the millisecond level. Given this, there have been proposals for, for example, EES-compatible substrate processing equipment wherein value representation of sensor data is performed by the process unit, for the processes handled by the equipment, or by fixed time units, where the representative values are checked. See, for example, Japanese Unexamined Patent Application Publication No. 2010-219460 (“the JP '460”). The representative values are maximum values, minimum values, average values, and the like. Achieving FD/FP through representative values, when compared to monitoring all data, enables a major reduction in the communication overhead, the required memory capacity, and the like, thus contributing to efficiency.

Known cases of FD/FP wherein representative values are used include FP for heater element burnout due to wearing out over time and FD for heater element burnout due to over-current. In a case of a heater wearing out over time, the average value for the resistance value (a non-process volume) of the heater gradually rises over time, so checking the average value of the resistance value for the heater as the representative value, makes it possible to predict burnout of the heater due to wearing out over time. Moreover, in the case of burnout of a heater element due to over-current, the maximum value of the resistance value for the heater rises suddenly, and thus checks that use the maximum value of the heater resistance value as the representative value are able to detect burnout of a heater due to over-current.

FD/FP can be implemented for a non-process volume, as described above. However, when it comes to process volumes, there are few places where in FD/FP can be achieved using only representative values such as is done for non-process volumes, and thus there is a problem in that it is not possible to fully implement the FD/FP function. Because a decentralized arrangement within EES equipment is an effective method of implementation in order to increase the overall efficiency of EES, there are calls for further strengthening the FD/FP functions on the sensor device level.

The present invention was created in order to solve the problems set forth above, and an aspect thereof is to provide a fault detecting system and fault detecting method able to strengthen the FD/FP function using process volumes on the device level (and, in particular, on the sensor device level). In other words, the present invention is to provide easy FD/FP-related functions that can be built-in, or added on, on the sensor device level.

### SUMMARY

A fault detecting system according to the present invention includes data acquiring means for acquiring, as state quantities for process volumes, time series data of the state quantity; representative value storing means for storing, as a representative value, a combination of the maximum value for a state quantity rate-of-change and the state quantity when the state quantity rate-of-change reached the maximum value; rate-of-change calculating means for calculating a state quantity rate-of-change based on state quantity data acquired by the data acquiring means; representative value updating means for updating the representative values that are stored in the representative value storing means to a combination of the most recent state quantity rate-of-change calculated by the rate-of-change calculating means and the most recent state quantity acquired by the data acquiring means, when the absolute value of the most recent state quantity rate-of-change calculated by the rate-of-change calculating means is larger than the absolute value of the maximum value of the state quantity rate-of-change stored in the representative value storing means; and resetting means for resetting, to a minimum value, the maximum value of the state quantity rate-of-change stored in the representative value storing means, when a reset signal has been received from the outside.

One configuration of a fault detecting system according to the present invention further includes data storing means for storing temporarily data for the most recent state quantities in an amount that is specified in advance; transient state storing means for storing, as transient state data relating to the representative values, state quantity data when a representative value has been updated by representative value updating means; and transient state updating means for updating, to the state quantity data stored in the data storing means, the transient state data that is stored in the transient state data storing means, when the representative value has been updated by the representative value updating means.

Moreover, one configuration of a fault detecting system according to the present invention further includes related data acquiring means for acquiring, as related data, data of at least one process volume related to the process volume that is the subject of the data acquiring means; related value storing means for storing related data when a representative value has been updated by the representative value updating means; and related value updating means for updating, to related data obtained by the related data acquiring means, the related data that is stored in the related data storing means, when the representative value has been updated by the representative value updating means.

Moreover, one configuration of a fault detecting system according to the present invention further includes representative value displaying means for displaying a representative value that is stored in the representative value storing means; and reset operating means for transmitting the reset signal to the resetting means in response to an operation from the outside.

Moreover, one configuration of a fault detecting system according to the present invention further includes representative value acquiring means for acquiring, at specific periods that are specified in advance, a representative value that is stored in the representative value storing means; reset value transmitting means for transmitting the reset signal to the resetting means after a representative value has been acquired by the representative value acquiring means; representative value history storing means for storing, in the order in which they were acquired, representative values acquired by the representative value acquiring means; first evaluating means for calculating an absolute value of a difference between a state quantity that is stored as a representative value in the representative value history storing means and the most recent state quantity acquired as a representative value by the representative value acquiring means, for each representative value that is stored in the representative value history storing means when a representative value is acquired by the representative value acquiring means, and for evaluating as a fault detection or as a state wherein a fault is predicted, and outputting a first alarm if at least one absolute value exceeds a first threshold value that has been specified in advance; and second evaluating means for calculating an absolute value of a difference between a state quantity rate-of-change highest value that is stored as a representative value in the representative value history storing means and the most recent state quantity rate-of-change highest value acquired as a representative value by the representative value acquiring means, for each representative value that is stored in the representative value history storing means when a representative value is acquired by the representative value acquiring means, and for evaluating as a fault detection or as a state wherein a fault is predicted, and outputting a second alarm if at least one absolute value exceeds a second threshold value that has been specified in advance.

Moreover, in one configuration of a fault detecting system according to the present invention: the process volume that is the subject of the data acquiring means is a measured value of a temperature sensor within a heating device; and the actuator that applies the state quantity change for the process volume that is the subject of the data acquiring means is a heater of the heating device.

Moreover, in one configuration of a fault detecting system according to the present invention: the process volume that is the subject of the data acquiring means is a measured value of a pressure sensor within vacuum equipment; and the actuator that applies the state quantity change for the process volume that is the subject of the data acquiring means is a vacuum pump of the vacuum equipment.

Moreover, in one configuration of a fault detecting system according to the present invention: the process volume that is the subject of the data acquiring means is a measured value of a flow rate sensor within fluid transporting equipment; and the actuator that applies the state quantity change for the process volume that is the subject of the data acquiring means is a control valve of the fluid transporting equipment and a fluid transporting pressure generating device.

Moreover, in one configuration of a fault detecting system according to the present invention: the process volume that is the subject of the data acquiring means is a measured value of a supply air temperature sensor within an air-conditioning system; and the actuator that applies the state quantity change for the process volume that is the subject of the data acquiring means is a cooling/heating water flow rate controlling valve and a water feeding pump in the air-conditioning.

Moreover, in one configuration of a fault detecting system according to the present invention: the process volume that is the subject of the data acquiring means is a measured value of a temperature sensor within a reaction furnace; and the actuator that applies the state quantity change for the process volume that is the subject of the data acquiring means is a heater of the reaction furnace.

A fault detecting method according to the present invention includes a data acquiring step for acquiring, as state quantities for process volumes, time series data of the state quantity; a rate-of-change calculating step for calculating a state quantity rate-of-change based on state quantity data acquired in the data acquiring step; a representative value updating step for referencing representative value storing means wherein are stored, as representative values, combinations of the state quantity rate-of-change highest values and state quantities when the state quantity rate-of-change highest values were reached, and for updating the representative values that are stored in the representative value storing means to a combination of the most recent state quantity rate-of-change calculated in the rate-of-change calculating step and the most recent state quantity acquired in the data acquiring step, when the absolute value of the most recent state quantity rate-of-change calculated in the rate-of-change calculating step is larger than the absolute value of the maximum value of the state quantity rate-of-change stored in the representative value storing means; and a resetting step for resetting, to a minimum value, the maximum value of the state quantity rate-of-change stored in the representative value storing means, when a reset signal has been received from the outside.

One configuration of a fault detecting method according to the present invention further includes a data storing step for storing temporarily data for the most recent state quantities in an amount that is specified in advance; and a transient state updating step for updating, to the state quantity data stored in the data storing means, the transient state data that is stored in transient state data storing means as transient state data related to the representative value, when the representative value has been updated in the representative value updating step.

One configuration of a fault detecting method according to the present invention further includes a related data acquiring step for acquiring, as related data, data of at least one process volume related to the process volume that is the subject of the data acquiring step; and a related value updating step for updating, to related data obtained in the related data acquiring step, the related data that is stored in the related data storing means, when the representative value has been updated in the representative value updating step.

One configuration of a fault detecting method according to the present invention further includes a representative value displaying step for displaying a representative value that is stored in the representative value storing means; and a reset operating step for transmitting a reset signal in response to an operation from the outside.

One configuration of a fault detecting method according to the present invention further includes a representative value acquiring step for acquiring, at specific periods that are specified in advance, a representative value that is stored in the representative value storing means; a reset value transmitting step for transmitting a reset signal after a representative value has been acquired in the representative value acquiring step; a first evaluating step, for referencing a representative value history storing means wherein is stored, sequentially, representative values acquired in the representative value acquiring step, and for calculating an absolute value of a difference between a state quantity that is stored as a representative value in the representative value history storing means and the most recent state quantity acquired as a representative value in the representative value acquiring step, for each representative value that is stored in the representative value history storing means when a representative value is acquired in the representative value acquiring step, and for evaluating as a fault detection or as a state wherein a fault is predicted, and outputting a first alarm if at least one absolute value exceeds a first threshold value that has been specified in advance; and a second evaluating step for calculating an absolute value of a difference between a state quantity rate-of-change highest value that is stored as a representative value in the representative value history storing means and the most recent state quantity rate-of-change highest value acquired as a representative value in the representative value acquiring step, for each representative value that is stored in the representative value history storing means when a representative value is acquired in the representative value acquiring step, and for evaluating as a fault detection or as a state wherein a fault is predicted, and outputting a second alarm if at least one absolute value exceeds a second threshold value that has been specified in advance.

In the present invention, the provision of the data acquiring means, the representative value storing means, the rate-of-change calculating means, and the representative value updating means enables storing, as representative volumes, a combination of the maximum value for the state quantity rate-of-change and the state quantity when the state quantity rate-of-change achieved that value, enabling strengthening of the FD/FP functions for process volumes on the device level (and, in particular, on the sensor device level). In the present invention, the data acquiring means, representative value storing means, rate-of-change calculating means, and representative value updating means can be built-in in a sensor device, or can be provided external to the sensor device.

Moreover, in the present invention, provision of the data storing means, the transient state storing means, and the transient state updating means enables state quantity data to be acquired, as transient state data related to the representative value, when a representative value is updated, enabling the transient state data to be of use when the operator performs analysis of the causes of the fault in the sensor or actuator.

Moreover, the provision of the related data acquiring means, the related value storing means, and the related value updating means in the present invention enables the acquisition of data for one or more process volumes to be acquired as related data, relating to the applicable process volumes, when the representative value is updated, enabling the operator to use the related data in the analysis of the cause of a fault in a sensor or actuator.

Moreover, in the present invention, the provision of the representative value displaying means enables the operator to read the representative value, enabling the operator to evaluate whether or not there is a fault in a sensor or actuator, and whether or not there is the possibility of a fault occurring in a sensor or an actuator.

Moreover, in the present invention, the provision of the representative value acquiring means, the reset signal transmitting means, the representative value history storing means, the first evaluating means, and the second evaluating means enables the achievement of FD/FP functions.

### BRIEF DESCRIPTIONS OF THE DRAWINGS

FIG. 1 is a block diagram illustrating a structure for a fault detecting system according to Example according to the present invention.

FIG. 2 is a flowchart illustrating the operation of the fault detecting system according to the Example according to the present invention.

FIG. 3 is a block diagram illustrating a structure for a fault detecting system according to Another Example according to the present invention.

FIG. 4 is a flowchart illustrating the operation of the fault detecting system according to the Another Example according to the present invention.

FIG. 5 is a block diagram illustrating a structure for a fault detecting system according to Still Another Example according to the present invention.

FIG. 6 is a diagram illustrating an operating example of a heating device according to the Still Another Example according to the present invention.

FIG. 7 is a block diagram illustrating a configuration for a heating device according to Yet Still Another Example according to the present invention.

FIG. 8 is a block diagram illustrating a structure of a vacuum device according to Further Example according to the present invention.

FIG. 9 is a block diagram illustrating a structure of a liquid conveying device according to Another Further Example according to the present invention.

FIG. 10 is a block diagram illustrating configuration of an air-conditioning system according to Still Another Further Example according to the present invention.

FIG. 11 is a block diagram illustrating a structure of a chemical plant reaction furnace according to Yet Still Another Further Example according to the present invention.

### DETAILED DESCRIPTION

### Principle

The present inventor noticed the following properties:

(A) When capabilities of a heater, capabilities of an air-conditioning pump, or the like, breakdown, there is a tendency to break down at the highest level reached by a state quantity rate-of-change (the rate-of-change of a temperature, pressure, or the like).

(B) When there is a shift in the measurement characteristics of a sensor (a measurement instrument), there is a tendency for the shift to be at the maximum point reached by a state quantity rate-of-change (the temperature, pressure, or the like, where the maximum level is reached for the increase in temperature, decrease in pressure, etc.).

(A) and (B), above, will be explained using temperature as an example. When there is an increase in temperature, if the same heating process is always performed once during a specific period, then the state quantity (the maximum capability point) and the maximum value for the state quantity rate-of-change (the maximum capability volume) when a state quantity rate-of-change has reached a maximum value, such as, for example, “when heating, the rate-of-change of temperature is observed at near to 0.50° C./sec. as the temperature passes 200° C.,” are handled as the representative state (the diagnosable information) for equipment performance (repeatability).

Moreover, because the state quantity when the state quantity rate-of-change reaches the maximum value, and the maximum value for the state quantity rate-of-change, do not require detailed settings in advance, they are handled easily by the user. That is, they can simply be involved in an evaluation process such as described below.

(C) If the maximum rate of temperature increase when passing through 200° C. is 0.45° C./sec., this is lower than the maximum capability volume of 0.50° C./sec., so it is suspected that the heater may be breaking down.

(D) If the temperature when the maximum rate of increase in temperature of 0.50° C./sec. has been reached is 203° C., then this is a shift from the maximum capability point of 200° C., so it is suspected that there might have been a shift in the temperature sensor.

In this way, it is useful to store, as representative values, a combination of the state quantity (the maximum capability point) when the state quantity rate-of-change has reached a maximum value and the maximum value (the maximum capability volume) for the state quantity rate-of-change, and the function for storing the representative value can be built-in at the sensor device level. The inventor contemplated the achievement of an FD/FP function through a combination with a function for acquiring representative values at periods that have been set in advance.

### Another Principle

While, in order to decentralize the FD/FP functions on the device level there is a strategy of limiting to effective value representation, as described above, the purpose for the use of representative values is to reduce the communication overhead, the required memory capacity, and the like, and thus there is no need to always be only representative values. Given this, the present inventor contemplates that it is useful to store transient state data from before and after the point in time at which the maximum value for the state quantity rate-of-change has been measured, to enable cooperation with a sophisticated FD/FP function.

### Still Another Principle

As with the Another Principle, this focuses on the fact that there is no need to always limit to only the representative values. Specifically, the inventor contemplates the benefit of storing simultaneously other related sensor measurement values at the point in time at which the maximum value for the state quantity rate-of-change has been measured, to enable cooperation with a sophisticated FD/FP function.

### Example

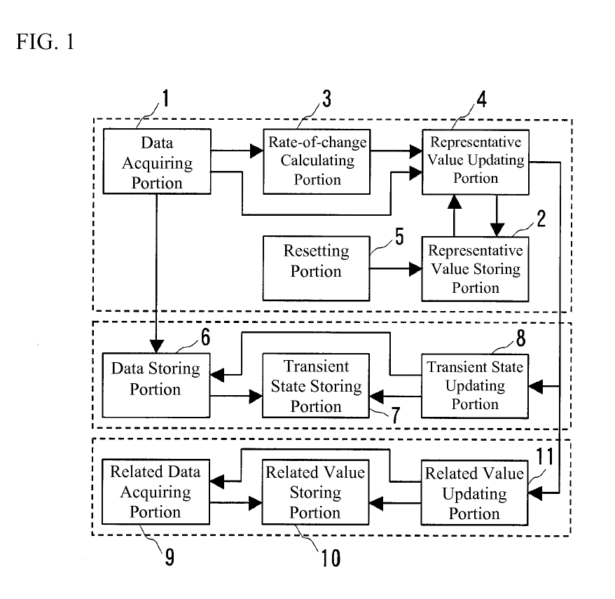

Forms for carrying out the present invention will be explained below in reference to the figures. FIG. 1 is a block diagram illustrating a structure for a fault detecting system according to Example according to the present invention. The present example corresponds to the Principle, the Another Principle, and the Still Another Principle, described above. A fault detecting system according to the present example includes: a data acquiring portion 1 that acquires time-series data of a state quantity, using a process volume as the applicable state quantity; a representative value storing portion 2 that stores, as a representative value, a combination of the maximum value for the state quantity rate-of-change and the state quantity when the state quantity rate-of-change reaches the maximum value; a rate-of-change calculating portion 3 that calculates a state quantity rate-of-change based on state quantity data acquired by the data acquiring portion 1; a representative value updating portion 4 that updates the representative values stored in the representative value storing portion 2, to the most recent state quantity rate-of-change that has been calculated by the rate-of-change calculating portion 3 and the most recent state quantity that has been acquired by the data acquiring portion 1, when the absolute value of the most recent state quantity rate-of-change that has been calculated by the rate-of-change calculating portion 3 is larger than the absolute value of the maximum value for the state quantity rate-of-change that is stored in the representative value storing portion 2; and a resetting portion 5 that resets, to a minimum value (for example, 0.0), the maximum value for the state quantity rate-of-change that is stored in the representative value storing portion 2 when a reset signal has been received from the outside.

The fault detecting system further includes: a data storing portion 6 that stores temporarily the most recent data for the state quantity of a volume that has been specified in advance; a transient state storing portion 7 that stores, as transient state data that is related to the representative value, state quantity data when the representative value has been updated by the representative value updating portion 4; and a transient state updating portion 8 that updates, to state quantity data that is stored in the data storing portion 6, the transient state data that is stored in the transient state storing portion 7, when the representative value has been updated by the representative value updating portion 4.

The fault detecting system further includes: a related data acquiring portion 9 that acquires, as related data, data for at least one process volume that is related to the process volume that is the subject of the data acquiring portion 1; a related value storing portion 10 that stores related data, when the representative value has been updated by the representative value updating portion 4; and a related value updating portion 11 that updates, to the related data acquired by the related data acquiring portion 9, the related data that is stored in the related value storing portion 10, when the representative value has been updated by the representative value updating portion 4.

The data acquiring portion 1, the representative value storing portion 2, the rate-of-change calculating portion 3, the representative value updating portion 4, and the resetting portion 5 are structures corresponding to the Principle, described above, the data storing portion 6, the transient state storing portion 7, and the transient state updating portion 8 are structures corresponding to the Another Principle, described above, and the related data acquiring portion 9, related value storing portion 10, and related value updating portion 11 are structures corresponding to the Still Another Principle, described above.

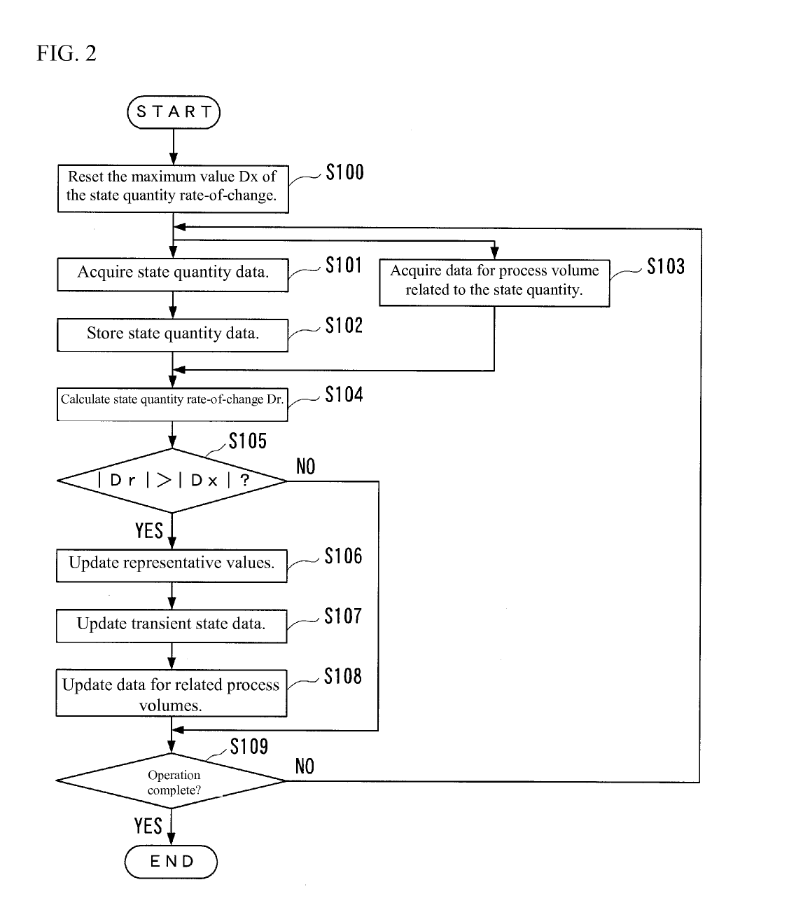

The operation of the fault detecting system according to the present example will be explained below, referencing FIG. 2. First, in the initial state, the resetting portion 5, having received a reset signal from the outside, resets, to a minimum value (for example, 0.0), the maximum value Dx of the state quantity rate-of-change that is stored in the representative value storing portion 2 (Step S100 in FIG. 2).

The data acquiring portion 1 acquires data of a state quantity (a process volume) from a sensor, not shown, that is the subject of observation (Step S101 in FIG. 2).

The data storing portion 6 receives the state quantity data from the data acquiring portion 1 and stores temporarily a predetermined amount (for example, 20 samples) of the most recent state quantity data (Step S102 in FIG. 2). When the procedure in Step S101 has been executed just once, only one sample worth of the most recent state quantity data will have been acquired, so each time the data acquiring portion 1 acquires one sample worth of data, the stored content in the data storing portion 6 will be updated. Note that the amount of data stored in the data storing portion 6 may be specified as a number of samples, or as the measurement time from the oldest data until the most recent data stored in the data storing portion 6.

In parallel with the processes in Step S101 and S102, the related data acquiring portion 9 acquires data of at least one process volume that is related to the state quantity (process volume) that is the subject of the data acquiring portion 1 (Step S103).

Following this, the rate-of-change calculating portion 3 calculates the state quantity rate-of-change Dr such as in the following equation based on the state quantity data received from the data acquiring portion 1 (Step S104):

Dr=D1−D2 (1).

In Equation (1), D1 is the most recent state quantity data and D2 is the state quantity data from the immediately previous sample.

Note that if, for example, the state quantity is a temperature, then the state quantity rate-of-change Dr in Equation (1) will have units of ° C./sample. If one wishes the units to be ° C./sec., then the state quantity rate-of-change Dr may be calculated, for example, as in Equation (2):

Dr=(D1−D2)/T1 (2)

In Equation (2), T1 is the sampling period (in seconds) for the state quantity. Following this, the representative value updating portion 4 evaluates whether or not the absolute value of the most recent state quantity rate-of-change Dr, calculated by the rate-of-change calculating portion 3 is larger than the absolute value of the maximum value Dx of the state quantity rate-of-change that is stored in the representative value storing portion 2 (Step S105 in FIG. 2). If a state quantity that is rising is the subject of observation, then the evaluation as to whether or not the absolute value of the state quantity rate-of-change Dr is larger than the absolute value of the maximum value Dx for the state quantity rate-of-change, that is, the evaluation of whether or not |Dr| |Dx| is satisfied, is an evaluation of whether or not Dr>Dx is satisfied. On the other hand, if a state quantity that is falling is the subject of observation, then the evaluation of whether or not |Dr|>|Dx| is satisfied is an evaluation of whether or not Dr<Dx is satisfied.

If |Dr|>|Dx| is satisfied (YES in Step S105), then the representative value updating portion 4 updates the representative values that are stored in the representative value storing portion 2 (the combination of the maximum value Dx for the state quantity rate-of-change and the state quantity D at the time that the state quantity rate-of-change reached the maximum value Dx) to the combination of the most recent state quantity rate-of-change Dr, calculated by the rate-of-change calculating portion 3, and the most recent state quantity D1 (Step S106 in FIG. 2). When updating is performed in this way, the representative values are updated as Dx=Dr and D=D1.

If the representative values have been updated, then the transient state updating portion 8 updates the transient state data that is stored in the transient state storing portion 7 to the series of state quantity data that is stored in the data storing portion 6 (Step S107 in FIG. 2).

If the representative values have been updated, then the related value updating portion 11 updates, to the most recent process volume data acquired by the related data acquiring portion 9, the process volume data that is stored in the related value storing portion 10 (Step S108 in FIG. 2).

The processes in Step S101 through S108, as described above, are executed repetitively with each sampling period T1 until the operation of the fault detecting system is terminated by an instruction from an operator (YES in Step S109 in FIG. 2).

Given the above, in the present example the FD/FP functions that handle the maximum value Dx of the state quantity rate-of-change (the maximum capability volume) and the state quantity D when the state quantity rate-of-change reached the maximum value Dx (the maximum capability point) as the representative state (the diagnosable information) for the equipment performance (repeatability) can be decentralized to the device level. That is, for a temperature controlling system, it is possible to detect the breakdown of the heater or a shift in the temperature sensor without storing all of the data.

### Another Example

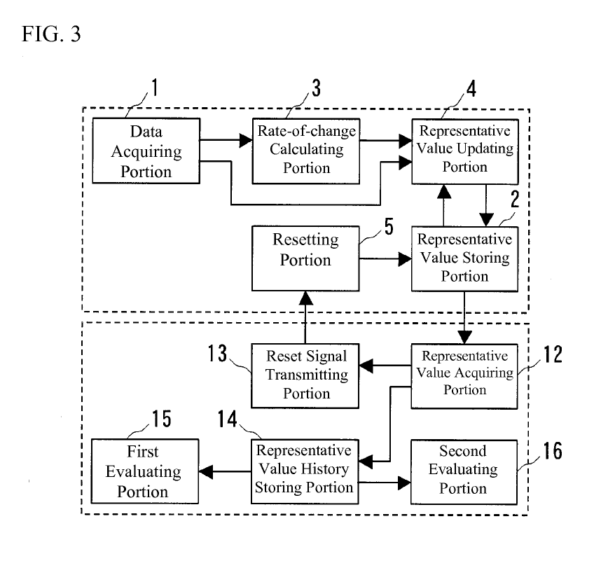

Another Example according to the present invention will be explained next. FIG. 3 is a block diagram illustrating a structure for a fault detecting system according to the Another Example according to the present invention. In the present example, an example is presented wherein the Example is used to achieve the FD/FP functions. In the present example, the explanation will be for a structure corresponding to the Principle, in order to clarify the significance of the Principle, described above.

The fault detecting system according to the present example includes: a data acquiring portion 1; a representative value storing portion 2; a rate-of-change calculating portion 3; a representative value updating portion 4; a resetting portion 5; a representative value acquiring portion 12 that acquires a representative value that has been stored in the representative value storing portion 2; a reset signal transmitting portion 13 that transmits a reset signal to the resetting portion 5 after the representative values have been acquired by the representative value acquiring portion 12; a representative value history storing portion 14 that stores the representative values, acquired by the representative value acquiring portion 12, in the order it in which they were acquired; a first evaluating portion 15 that calculates, for each of the individual representative values stored in the representative value history storing portion 14, the absolute values of the difference between the state quantity that is stored as a representative value in the representative value history storing portion 14 and the most recent state quantity that has been acquired as a representative value by the representative value acquiring portion 12, each time a representative value is acquired by the representative value acquiring portion 12, and if one or more absolute value exceeds a threshold value Dt that is specified in advance, outputs a fault notification or evaluates that there is a fault notification state and outputs an alarm A; and a second evaluating portion 16 that calculates, for each individual representative value stored in the representative value history storing portion 14, an absolute value of the difference between the maximum value for the state quantity rate-of-change stored as a representative value in the representative value history storing portion 14 and the maximum value for the most recent state quantity rate-of-change obtained from the representative values by the representative value acquiring portion 12, each time a representative value is acquired by the representative value acquiring portion 12, and if one or more absolute value exceeds a threshold value Dxt that is specified in advance, outputs a fault notification or evaluates that there is a fault notification state and outputs an alarm B.

The data acquiring portion 1, the representative value storing portion 2, the rate-of-change calculating portion 3, the representative value updating portion 4, and the resetting portion 5 are equipped in the sensor device, and the representative value acquiring portion 12, the reset signal transmitting portion 13, the representative value history storing portion 14, the first evaluating portion 15, and the second evaluating portion 16 are equipped in a subsystem including a controller such as a PLC (Programmable Logic Controller).

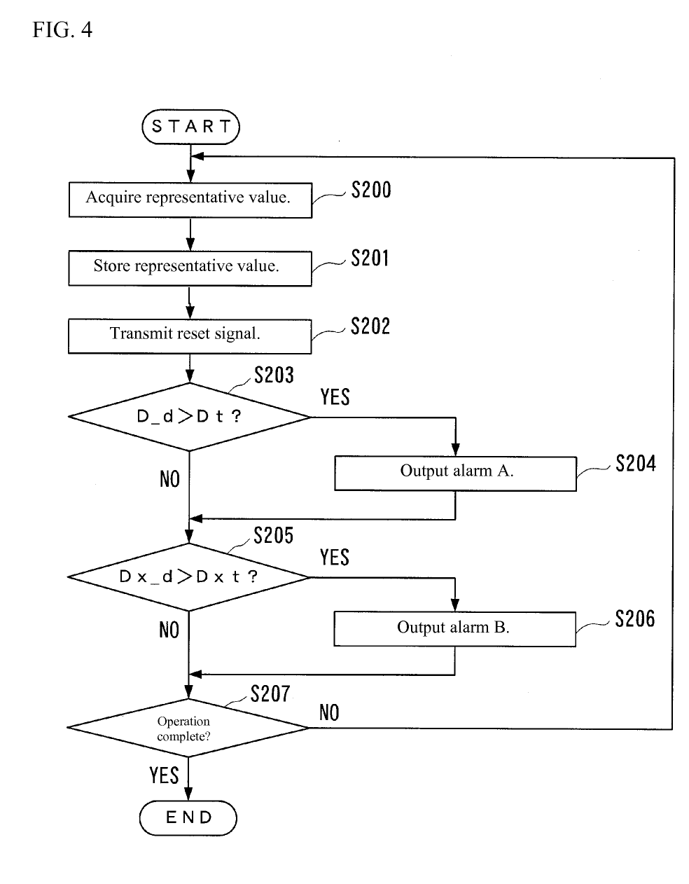

The operation of the fault detecting system according to the present example will be explained below, referencing FIG. 4. The operations of the data acquiring portion 1, the representative value storing portion 2, the rate-of-change calculating portion 3, the representative value updating portion 4, and the resetting portion 5 are as were explained in the Example.

At specific periods T2 that has been set in advance (where T1<T2, and T2 is, for example, one week), the representative value acquiring portion 12 acquires the representative values that have been stored in the representative value storing portion 2 of the sensor device side (where the representative values are combinations of the maximum values Dx for the state quantity rates-of-change and the state quantities D at the times that the state quantity rates-of-change reached the maximum values Dx) (Step S200 in FIG. 4).

The representative value history storing portion 14 stores the representative values obtained by the representative value acquiring portion 12 (Step S201 in FIG. 4).

The reset signal transmitting portion 13 sends a reset signal to the resetting portion 5 on the sensor device side after the representative value acquiring portion 12 has acquired the representative values (Step S202 in FIG. 4). Through doing so, the maximum value Dx for the state quantity rate-of-change stored in the representative value storing portion 2 is resetted by the resetting portion 5 to a minimum value (for example 0.0) (Step S100 in FIG. 2), and the representative value storing portion 2 is returned to the initial state, and the processes in Step S101 through S108 in FIG. 2 on the sensor device side are executed repeatedly with each sampling period T1. That is, during the specific period T2, Step S101 through S108 are performed multiple times, and the representative values obtained (the combinations of the maximum value Dx of the state quantity rate-of-change and the state quantity D when the state quantity rate-of-change reached the maximum value Dx) through performing these multiple times are acquired by the representative value acquiring portion 12, and so when the processes of Step S200 through S202 are executed with each specific period T2, historical data for the representative values is accumulated in the representative value history storing portion 14. Note that after the representative value history storing portion 14 has been filled with data of an amount that has been set in advance (a specific number of samples or over a specific measurement time), the oldest representative values that are recorded in the representative value history storing portion 14 may be deleted, so as to enable storing of the most recent representative values into the representative value history storing portion 14.

Following this, each time the representative value acquiring portion 12 acquires a representative value, the first evaluating portion 15 evaluates the absolute value D_d of a difference between an arbitrary state quantity D_old_i (where i=1 through n) that is stored as a representative value in the representative value history storing portion 14 and the most recent state quantity D_new that has been acquired as a representative value by the representative value acquiring portion 12, and evaluates whether or not the absolute value D_d is greater than a threshold value Dt that is set in advance (Step S203 in FIG. 4).

D_{—}d=|D_new−D_old_{—}i| (3)

For each state quantity D_old_i that is stored in the representative value history storing portion 14, the first evaluating portion 15 performs the evaluating process such as in this Step S203, and if at least one absolute value D_d that is calculated from a state quantity D_old_i exceeds the threshold value Dt (D_d>Dt), outputs and alarm A (Step S204 in FIG. 4).

On the other hand, each time the representative value acquiring portion 12 acquires a representative value, the second evaluating portion 16 evaluates the absolute value Dx_d of a difference between an arbitrary highest value Dx_old_i of a state quantity rate of change (where i=1 through n) that is stored as a representative value in the representative value history storing portion 14 and the most recent highest value Dx_new of a state quantity rate of change that has been acquired as a representative value by the representative value acquiring portion 12, and evaluates whether or not the absolute value Dx_d is greater than a threshold value Dxt that is set in advance (Step S205 in FIG. 4).

Dx_{—}d=|Dx_new−Dx_old_{—}i| (4)

For each highest value Dx_old_i of the state value rate-of-change that is stored in the representative value history storing portion 14, the second evaluating portion 16 performs the evaluating process such as in this Step S205, and if at least one absolute value Dx_d that is calculated from a highest value Dx_old_i exceeds the threshold value Dxt (Dx_d>Dxt), outputs and alarm B (Step S206 in FIG. 4).

The processes in Step S200 through S206 are executed repetitively with each specific period T2 until the operation of the fault detecting system is terminated by, for example, an instruction from an operator (YES in Step S207 in FIG. 4).

Given the above, in the case of, for example, a temperature controlling system, the alarm A can be used as an alarm for a shift in the temperature sensor. Moreover, in the case of a temperature controlling system, the alarm B can be used as an alarm for breakdown of the heater.

Note that if the data storing portion 6, the transient state storing portion 7, the transient state updating portion 8, the related data acquiring portion 9, the related value storing portion 10, and the related value updating portion 11 are provided on the sensor device side or the subsystem side, then when the representative values are acquired or when alarms are outputted, the data that are stored in these structures may be acquired as well, facilitating the operator in analyzing the cause of the alarm. That is, for a temperature controlling system, it is possible to secure data that is effective in analyzing breakdown of a heater or a shift in the temperature sensor, for example, without storing all of the data.

### Still Another Example

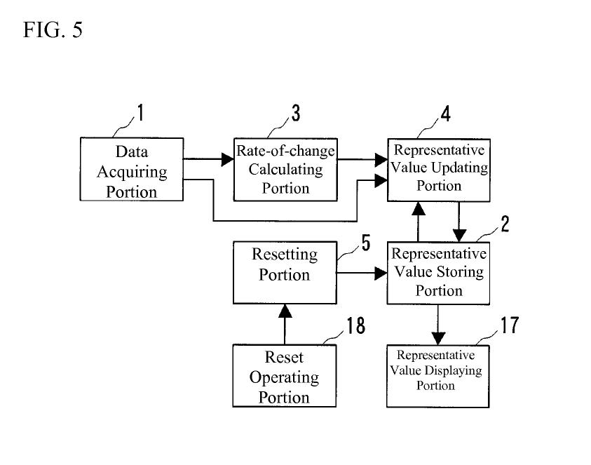

Still Another Example according to the present invention will be explained next. FIG. 5 is a block diagram illustrating a structure for a fault detecting system according to the Still Another Example according to the present invention. In the present example, an example of a device is presented wherein the Example is used to achieve the FD/FP functions. In the present example, the explanation will be for a structure corresponding to the Principle, in order to clarify the significance of the Principle, described above.

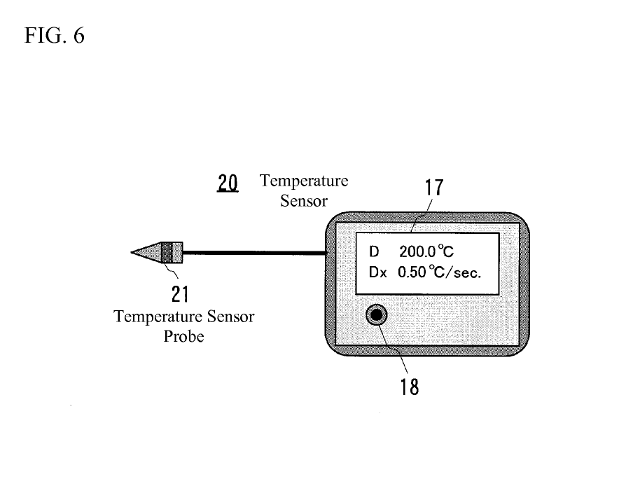

A fault detecting system according to the present example includes: a data acquiring portion 1; a representative value storing portion 2; a rate-of-change calculating portion 3; a representative value updating portion 4; a resetting portion 5; a representative value displaying portion 17 that displays a representative value that is stored in the representative value storing portion 2; and a reset operating portion 18, such as a manual switch, which sends a reset signal to the resetting portion 5 in response to an operation from the outside. The structure in FIG. 5 is provided on the sensor device. An external view of a case wherein the structure in FIG. 5 is provided in a temperature sensor 20 is shown in FIG. 6.

An operator, following specified operating procedures, periodically (for example, each time one week elapses) performs a reset by performing an operation on the reset operating portion 18. Doing so causes a reset signal to be sent from the reset operating portion 18 to the resetting portion 5, so the resetting portion 5 resets the maximum value Dx for the state quantity rate-of-change that is stored in the representative value storing portion 2 to the minimum value (for example, 0.0), thus returning the representative value storing portion 2 to the initial state.

The operations of the data acquiring portion 1, the representative value storing portion 2, the rate-of-change calculating portion 3, and the representative value updating portion 4 are as were explained in the Example.

The representative value displaying portion 17 displays the representative values stored in the representative value storing portion 2 (the maximum value Dx for the state quantity rate-of-change and the state quantity D at the time that the state quantity rate-of-change reached the maximum value Dx). This enables the operator to read out the representative values. If the operator has recorded a representative value history, the operator can perform on his/her own the same evaluation as in the Another Example.

If there is a plurality of devices used under identical conditions, then the differences between representative values between the multiple devices can be used by the operator himself/herself to focus on potential faults where there is a remarkable difference. For example, if, among 10 devices, nine of the devices display essentially the same representative values, but only a single device displays a maximum value Dx for the state quantity rate-of-change that is remarkably degraded, then that single device can be seen to be a potential fault.

As described above, in the present example the provision of a representative value displaying portion 17 and a reset operating portion 18 can enable the achievement of an FD/FP function in a scope that can be implemented easily on, for example, even a sensor device.

Note that while in the prior art the decentralized distribution of the EES within devices was addressed as the issue, the above Example through Still Another Examples are not limited to EES's, but rather may be implemented in a range that applies also to the level of devices used in air-conditioning control in buildings, in chemical plants, and the like. Of course, the above Example through Still Another Example may be combined as appropriate.

### Yet Still Another Example

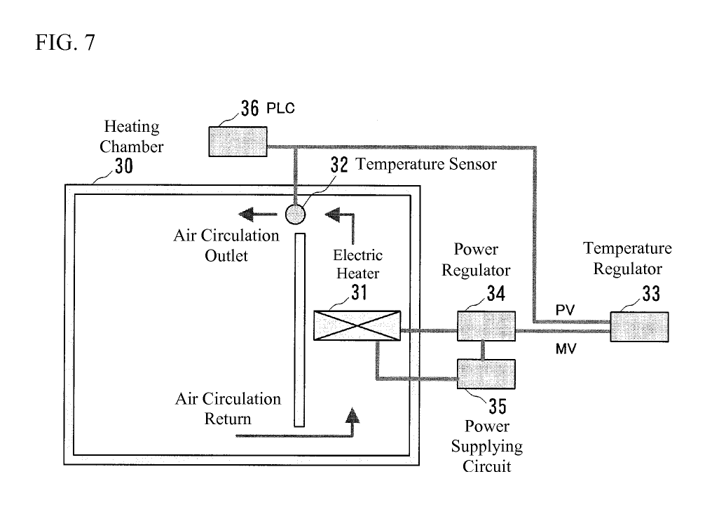

Yet Still Another Example according to the present invention will be explained next. The present example will use, as an example, a case wherein the fault detecting systems set forth in the Example and Another Example are applied to a temperature controlling system of a heating device. FIG. 7 is a block diagram illustrating a structure for a heating device. The heating device is structured with: a heating chamber 30 for heating an object that is to be heated, subject to processing; an electric heater 31 that is an actuator for heating; a temperature sensor 32 that measures the temperature within the heating chamber 30; a temperature regulator 33 that controls the temperature within the heating chamber 30; a power regulator 34; a power supplying circuit 35; and a PLC 36 that controls the heating device as a whole.

The temperature regulator 33 calculates an operating volume MV so that a temperature PV that is measured by a temperature sensor 32 will go to a temperature setting value. The power regulator 34 determines the electric power in accordance with the operating volume MV, and supplies, to an electric heater 31 through the power supplying circuit 35, the power that has been determined. In this way, the temperature regulator 33 controls the temperature of the object that is heated within the heating chamber 30.

The data acquiring portion 1, the representative value storing portion 2, the rate-of-change calculating portion 3, the representative value updating portion 4, and the resetting portion 5 of FIG. 1 are provided in the temperature sensor 32 that is the sensor device, and the representative value acquiring portion 12, the reset signal transmitting portion 13, the representative value history storing portion 14, the first evaluating portion 15, and the second evaluating portion 16 of FIG. 3 are provided in the PLC 36. Note that the data acquiring portion 1, the representative value storing portion 2, the rate-of-change calculating portion 3, the representative value updating portion 4, and the resetting portion 5 may instead be provided in the temperature regulator 33.

In the manufacturing process that uses the heating device, there may be various changes in temperature and various heating processes depending on the product being manufactured, but the heating patterns are limited, and it is assumed that within a one-week period, all of the heating patterns will be executed. Of these, in a heating pattern that normally goes from 50° C. to 400° C., for example, the highest temperature ramp-up rate (the maximum value Dx for the state quantity rate-of-change) is observed (at, for example, 0.50° C./sec. when passing through 200° C.). Note that in the present example it is assumed that the maximum value Dx for the state quantity rate-of-change does not increase on its own

The data acquiring portion 1 acquires state quantity (temperature PV) data, measured by the temperature sensor 32. The operations of the representative value storing portion 2, the rate-of-change calculating portion 3, the representative value updating portion 4, and the resetting portion 5 are as were explained in the Example.

### Fault Detecting Example 1

Here it is assumed that the representative value acquiring portion 12 acquires the representative values (the maximum values Dx for the state quantity rate-of-change and the state quantities D at the time that the state quantity rate-of-change reached the maximum value Dx) from the representative value storing portion 2 periodically with an interval of T2 (one week), and that representative value historical data of D=200.0° C. and Dx=0.50° C./sec. for week 1, D=199.9° C. and Dx=0.51° C./sec. for week 2, D=200.1° C. and Dx=0.49° C./sec. for week 3, D=200.8° C. and Dx=0.50° C./sec. for week 17, D=200.9° C. and Dx=0.51° C./sec. for week 18, D=202.5° C. and Dx=0.51° C./sec. for week 27, D=202.8° C. and Dx=0.50° C./sec. for week 28, D=203.0° C. and Dx=0.49° C./sec. for week 29, and D=203.1° C. and Dx=0.50° C./sec. for week 30 are stored in the representative value history storing portion 14.

The first evaluating portion 15, when calculating the absolute value D_d of the difference between the most recent state quantity D acquired by the representative value acquiring portion 12 and each state quantity D that is stored in the representative value history storing portion 14, once per week (each time the representative value acquiring portion 12 acquires the representative values), in week 29, the absolute value D_d will be 3.1° C. between the most recent state quantity D=203.0° C. and the state quantity D=199.9° C. for the second week, which exceeds the threshold value Dt=3.0° C. which has been set in advance, so the alarm A is outputted. Moreover, the absolute value D_d will be 3.2° C. between the most recent state quantity D=203.1° C. and the state quantity D=199.9° C. for the second week, which exceeds the threshold value Dt=3.0° C. which has been set in advance, so the first evaluating portion 15 outputs the alarm A.

Given that the alarm A has been outputted, the operator considers the possibility that there has been a shift in the temperature sensor 32, and can decide to perform an inspection.

Note that if the temperature sensor 32, the temperature regulator 33, or the PLC 36 is provided with the data storing portion 6, the transient state storing portion 7, the transient state updating portion 8, the related data acquiring portion 9, the related value storing portion 10, and the related value updating portion 11, then it will be possible to acquire the time series data for the temperature PV, and temperatures of other parts in the heating device, and the like, before and after the temperature PV went past 203.0° C. Given this, the operator is able to use this additional information in analyzing the cause of the alarm.

For example, the operator can use the time series data for the temperature PV before and after the temperature PV crossed 203.0° C. to calculate the temperature ramp-up rate near when the temperature PV crossed 200.0° C., to determine whether or not there was a remarkable difference. Moreover, the operator can check the temperature at other places within the heating device when the temperature PV crossed 203.0° C., to determine whether it is the entire environment within the heating device that has shifted, or only the temperature sensor 32.

### Fault Detecting Example 2

Here it is assumed that the representative value acquiring portion 12 acquires the representative values (the maximum values Dx for the state quantity rate-of-change and the state quantities D at the time that the state quantity rate-of-change reached the maximum value Dx) from the representative value storing portion 2 periodically with an interval of T2 (one week), and that representative value historical data of D=200.0° C. and Dx=0.49° C./sec. for week 1, D=199.9° C. and Dx=0.50° C./sec. for week 2, D=200.1° C. and Dx=0.49° C./sec. for week 3, D=200.0° C. and Dx=0.49° C./sec. for week 17, D=200.1° C. and Dx=0.48° C./sec. for week 18, D=200.2° C. and Dx=0.47° C./sec. for week 27, D=200.0° C. and Dx=0.46° C./sec. for week 28, D=199.9° C. and Dx=0.45° C./sec. for week 29, D=200.1° C. and Dx=0.45° C./sec. for week 30, are stored in the representative value history storing portion 14.

The second evaluating portion 16, when calculating the absolute value Dx_d of the difference between the most recent state quantity rate-of-change highest value Dx acquired by the representative value acquiring portion 12 and each state quantity rate-of-change highest value Dx that is stored in the representative value history storing portion 14, once per week (each time the representative value acquiring portion 12 acquires the representative values), in week 29, the absolute value Dx_d will be 0.05° C. between the most recent state quantity rate-of-change highest value Dx=0.045° C./sec. and the state quantity rate-of-change highest value Dx=0.50° C./sec. for the second week, which exceeds the threshold value Dxt=0.04° C./sec. which has been set in advance, so the alarm B is outputted. Moreover, the absolute value Dx_d will be 0.05° C./sec. between the most recent state quantity rate-of-change highest value Dx=0.45° C./sec. and the state quantity rate-of-change highest value Dx=0.50° C./sec. for the second week, which exceeds the threshold value Dxt=0.04° C./sec. which has been set in advance, so the second evaluating portion 16 outputs the alarm B.

Given that the alarm B has been outputted, the operator considers the possibility that there the electric heater 31 is breaking down, and can decide to perform an inspection.

Note that if the temperature sensor 32, the temperature regulator 33, or the PLC 36 is provided with the data storing portion 6, the transient state storing portion 7, the transient state updating portion 8, the related data acquiring portion 9, the related value storing portion 10, and the related value updating portion 11, then it will be possible to acquire the time series data for the temperature PV, the heater power value (the operating volume MV), and the like, before and after the temperature PV went past 199.9° C. Given this, the operator is able to use this additional information in analyzing the cause of the alarm.

For example, the operator can check heater power value (the operating volume MV) when the temperature PV crossed 199.9° C., to determine whether or not the power is different from the standard power of the heater that is recognized by the operator.

Note that in consideration of the tolerance error and variability of the representative values themselves, a smoothing process may be performed on the historic data for the representative values that are stored sequentially in the representative value history storing portion 14.

### Further Example

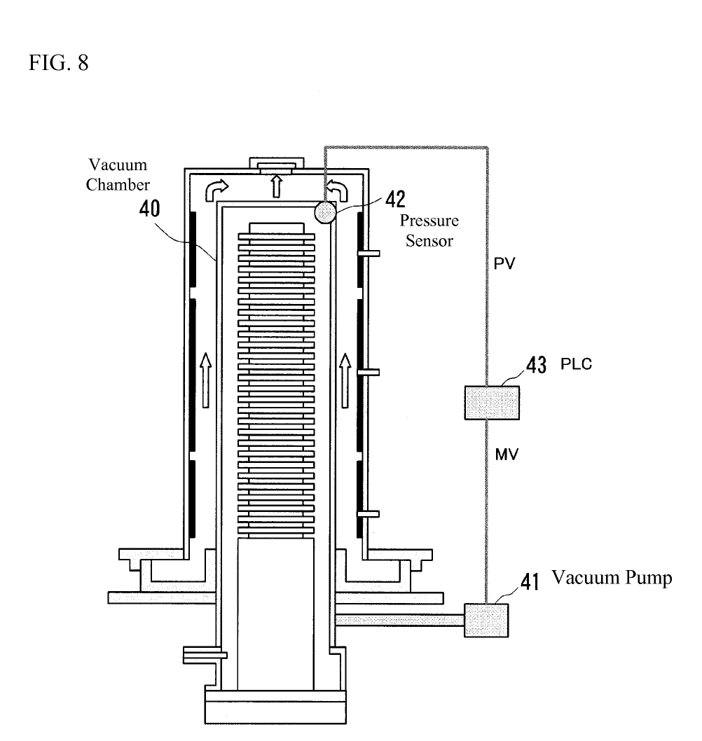

Further Example according to the present invention will be explained next. The present example will use, as an example, a case wherein the fault detecting systems set forth in the Example and Another Example are applied to a pressure controlling system for vacuum equipment. FIG. 8 is a block diagram illustrating a structure of the vacuum equipment. The vacuum equipment is structured with a vacuum chamber 40, a vacuum pump 41 that is an actuator for reducing the pressure, a pressure sensor 42 (a vacuum gauge) for measuring the pressure within the vacuum chamber 40, and a PLC 43 for controlling the vacuum equipment.

The PLC 43 calculates the operating volume MV so that the pressure PV that is measured by the pressure sensor 42 will go to a pressure setting value. The vacuum pump 41 draws a vacuum (reduces the pressure) in the vacuum chamber 40 depending on the operating volume MV. In this way, the PLC 43 controls the pressure within the vacuum chamber 40.

The data acquiring portion 1, the representative value storing portion 2, the rate-of-change calculating portion 3, the representative value updating portion 4, and the resetting portion 5 of FIG. 1 are provided in the pressure sensor 42 that is the sensor device, and the representative value acquiring portion 12, the reset signal transmitting portion 13, the representative value history storing portion 14, the first evaluating portion 15, and the second evaluating portion 16 of FIG. 3 are provided in the PLC 43.

In the production process that uses the vacuum chamber 40, the same vacuum (reduced pressure) is always drawn, where the pressure reduction pattern is executed several times in a day.

The data acquiring portion 1 acquires state quantity (pressure PV) data, measured by the pressure sensor 42. The operations of the representative value storing portion 2, the rate-of-change calculating portion 3, the representative value updating portion 4, and the resetting portion 5 are as were explained in the Example.

The representative value acquiring portion 12 may acquire, from the representative value storing portion 2, the representative values (the maximum value Dx for the state quantity rate-of-change and the state quantity D at the time that the state quantity rate-of-change reached the maximum value Dx), on a regular periodic basis at periods T2 (for example, one day). Moreover, the threshold values Dt and Dxt, used by the first evaluating portion 15 and the second evaluating portion 16, may be set as appropriate in advance.

In the present example, when the alarm A has been outputted from the first evaluating portion 15, the operator considers the possibility that there has been a shift in the pressure sensor 42, and can decide to perform an inspection.

Moreover, when the alarm B has been outputted from the second evaluating portion 16, the operator considers the possibility that there may be a fault such as a performance breakdown in the vacuum pump 41 or an air leak in the vacuum chamber 40, and can decide to perform an inspection.

### Another Further Example

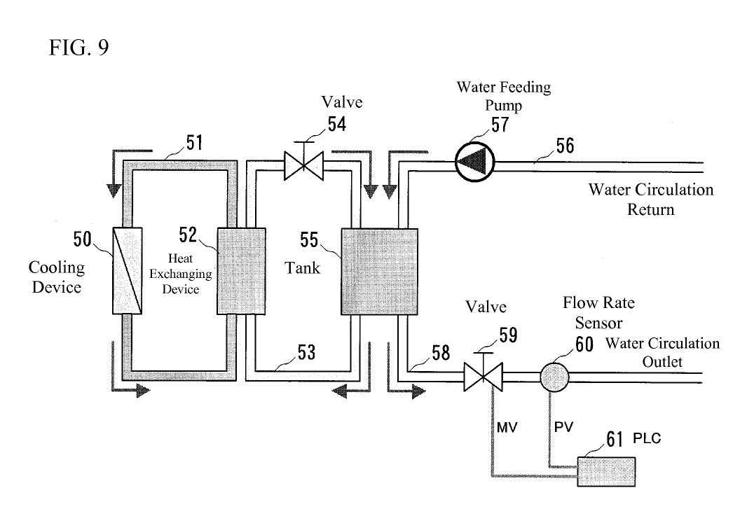

Another Further Example according to the present invention will be explained next. The present example will use, as an example, a case wherein the fault detecting systems set forth in the Example and Another Example are applied to a flow rate controlling system in the fluid transporting equipment (a cooling water supply device or a chiller). FIG. 9 is a block diagram illustrating a structure of the fluid transporting equipment. The fluid transporting device is structured with: a cooling device 50 that cools a refrigerant; a pipe 51 for circulating the refrigerant; a heat exchanging device 52; a pipe 53 for circulating cooling water; a valve 54; a tank 55; a supply pipe 56 for feeding water into the tank 55; a supply water pump 57 that is an actuator for feeding water into the tank 55 (a transporting pressure generating device that generates pressure for transporting the water); a pipe 58 in which the water that is fed out from the tank 55 flows; a control valve 59 that is an actuator that adjusts the flow rate of the water that is fed out from the tank 55; a flow rate sensor 60 that measures the flow rate of the water that is fed out from the tank 55; and a PLC 61 that controls the fluid transporting device.

The cooling device 50 cools the medium that circulates in the pipe 51. The heat exchanging device 52 performs heat exchange between the cooling medium and the water that flows in the supply pipe 53, where the cooled water is fed into the tank 55 through the supply pipe 53. Exchange of heat is performed by the cold water from the supply pipe 53 and the water fed by the cooling water pump 57 in the tank 55, and the water that has been cooled is fed out from the tank 55 to the pipe 58. The PLC 61 calculates an operating volume MV so that the flow rate PV, measured by the flow rate sensor 60, will go to a flow rate setting value. The degree of opening of the control valve 59 is determined in accordance with this operating volume MV. The PLC 61 controls the flow rate of the water thereby.

The data acquiring portion 1, the representative value storing portion 2, the rate-of-change calculating portion 3, the representative value updating portion 4, and the resetting portion 5 of FIG. 1 are provided in the flow rate sensor 60 that is the sensor device, and the representative value acquiring portion 12, the reset signal transmitting portion 13, the representative value history storing portion 14, the first evaluating portion 15, and the second evaluating portion 16 of FIG. 3 are provided in the PLC 61.

In the manufacturing process wherein the fluid transporting equipment is used, there is a process for changing the flow rate of the flow through the pipes and 56 and 58 from a state with a zero flow rate to the maximum flow rate every Monday morning (an increased flow rate process), where, for this reason, the increased flow rate pattern is executed once per week.

The data acquiring portion 1 acquires state quantity (flow rate PV) data, measured by the flow rate sensor 60. The operations of the representative value storing portion 2, the rate-of-change calculating portion 3, the representative value updating portion 4, and the resetting portion 5 are as were explained in the Example.

The representative value acquiring portion 12 may acquire, from the representative value storing portion 2, the representative values (the maximum value Dx for the state quantity rate-of-change and the state quantity D at the time that the state quantity rate-of-change reached the maximum value Dx), on a regular periodic basis at periods T2 (for example, one week). Moreover, the threshold values Dt and Dxt, used by the first evaluating portion 15 and the second evaluating portion 16, may be set as appropriate in advance.

In the present example, when the alarm A has been outputted from the first evaluating portion 15, the operator considers the possibility that there has been a shift in the flow rate sensor 60, and can decide to perform an inspection.

Moreover, when the alarm B has been outputted from the second evaluating portion 16, the operator considers the possibility that there may be a fault such as a performance breakdown in the water feeding pump 57 or in an operating portion of the control valve 59, and can decide to perform an inspection.

Note that while in the present example the explanation was for a fluid transporting device that transported water, there is no limitation thereto, but rather the fluid that flows in the pipes 56 and 58 may be air instead.

### Still Another Further Example

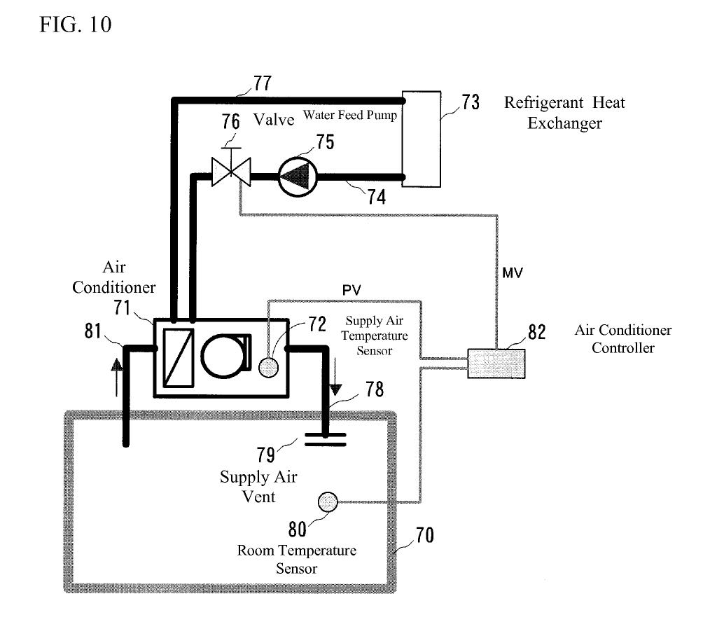

Still Another Further Example according to the present invention will be explained next. The present example will use, as an example, a case wherein the fault detecting systems set forth in the Example and Another Example are applied to a supply air temperature controlling system of an air-conditioning system. FIG. 10 is a block diagram illustrating a structure of the air-conditioning system. The air-conditioning system is structured with: an air conditioner 71; a supply air temperature sensor 72 that measures the temperature of supply air that is supplied from the air conditioner 71; a refrigerant heat exchanging device 73 that heats or cools a refrigerant (cold/hot water); a distribution pipe 74 wherein the cold/hot water that is fed from the refrigerant heat exchanging device 73 flows; a water feeding pump 75 that is an actuator for feeding the cold/hot water to the air conditioner 71; a cold/hot water flow rate controlling valve 76 that is an actuator that adjusts the flow rate of the cold/hot water that is supplied to the air conditioner 71; a pipe 77 for returning, to the refrigerant heat exchanging device 73, the cold/hot water that has been used by the air conditioner 71; a duct 78 for supplying, to a room 70, the supply air fed from the air conditioner 71; a supply air vent 79; a room temperature sensor 80; a duct 81 for returning air from the room 70 to the air conditioner 71; and an air conditioner controller 82 that controls the air-conditioning system.

The air-conditioning controller 82 calculates an operating volume MV to cause a supply air temperature PV, measured by the supply air temperature sensor 72, to go to the supply air temperature setting value. The degree of opening of the cold/hot water flow rate controlling valve 76 is determined in accordance with the operating volume MV, to regulate the flow rate of the cold/hot water that is supplied to the air conditioner 71. The supply air that is heated or cooled by the air conditioner 71 is fed to the room 70 through the duct 78 from the supply air vent 79. The air-conditioning controller 82 controls the blowing rate of the air conditioner 71 so that the room temperature measured by the room temperature sensor 80 will go to the room temperature setting value

The data acquiring portion 1, the representative value storing portion 2, the rate-of-change calculating portion 3, the representative value updating portion 4, and the resetting portion 5 of FIG. 1 are provided in the supply air temperature sensor 72 that is the sensor device, and the representative value acquiring portion 12, the reset signal transmitting portion 13, the representative value history storing portion 14, the first evaluating portion 15, and the second evaluating portion 16 of FIG. 3 are provided in the air conditioner controller 82.

While there is a variety of temperature variation patterns in air-conditioning control using the air conditioner 71, every morning the air conditioner 71 is switched from a stopped state to an operating state, and in the springtime and in the autumn the supply air temperature is controlled using full-power cooling or heating. Given this, it is assumed that circumstances do not occur wherein a maximum value Dx for the state quantity rate of change will be recorded at other than full power.

The data acquiring portion 1 acquires state quantity (supply air temperature PV) data, measured by the supply air temperature sensor 72. The operations of the representative value storing portion 2, the rate-of-change calculating portion 3, the representative value updating portion 4, and the resetting portion 5 are as were explained in the Example.

The representative value acquiring portion 12 may acquire, from the representative value storing portion 2, the representative values (the maximum value Dx for the state quantity rate-of-change and the state quantity D at the time that the state quantity rate-of-change reached the maximum value Dx), on a regular periodic basis at periods T2 (for example, one day). Moreover, the threshold values Dt and Dxt, used by the first evaluating portion 15 and the second evaluating portion 16, may be set as appropriate in advance. However, in the case of a building air conditioner, there is a tendency to be affected by the outside temperature and by heat sources within the space that is to be air condition, and thus, when compared to industrial manufacturing processes, the repeatability is poor, and thus preferably the threshold values Dt and Dxt should be specified somewhat on the high side for the amount of variability of the representative values. Moreover, preferably a smoothing process is performed on the historic data for the representative values that are stored sequentially in the representative value history storing portion 14.

In the present example, when the alarm A has been outputted from the first evaluating portion 15, the operator considers the possibility that there has been a shift in the supply air temperature sensor 72, and can decide to perform an inspection.

Moreover, when the alarm B has been outputted from the second evaluating portion 16, the operator considers the possibility that there may be a fault such as a performance breakdown in the water feeding pump 75 or in an operating portion of the cooling/heating water flow rate controlling valve 76, and can decide to perform an inspection.

### Yet Still Another Further Example

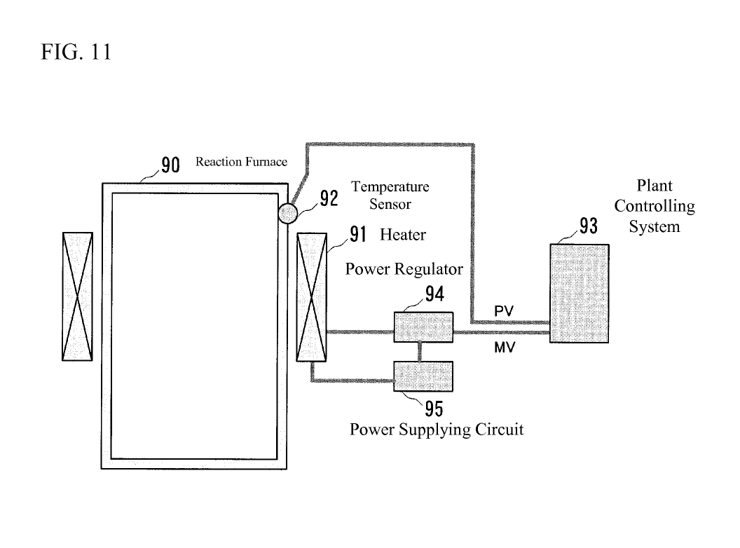

Yet Still Another Further Example according to the present invention will be explained next. The present example will use, as an example, a case wherein the fault detecting systems set forth in the Example and Anther Example are applied to a temperature controlling system of a chemical plant reaction furnace. FIG. 11 is a block diagram illustrating a configuration of a chemical plant reaction furnace. The chemical plant reaction furnace is structured with: a reaction furnace 90; a heater 91 that is a heating actuator; a temperature sensor 92 that measures the temperature within the reaction furnace 90; a plant controlling system 93 that controls the temperature within the reaction furnace 90; a power regulator 94; and a power supplying circuit 95.

The plant controlling system 93 calculates an operating volume MV so that a temperature PV that is measured by a temperature sensor 92 will go to a temperature setting value. The power regulator 94 determines the electric power in accordance with the operating volume MV, and supplies, to a heater 91 through the power supplying circuit 95, the power that has been determined. In this way, the plant controlling system 93 controls the temperature within the reaction furnace 90.

The data acquiring portion 1, the representative value storing portion 2, the rate-of-change calculating portion 3, the representative value updating portion 4, and the resetting portion 5 of FIG. 1 are provided in the temperature sensor 92 that is the sensor device, and the representative value acquiring portion 12, the reset signal transmitting portion 13, the representative value history storing portion 14, the first evaluating portion 15, and the second evaluating portion 16 of FIG. 3 are provided in the plant controlling system 93.

The manufacturing process wherein the chemical plant reaction furnace is used always has the same heating pattern, where the heating pattern is executed once every two or three days (several times a week).

The data acquiring portion 1 acquires state quantity (temperature PV) data, measured by the temperature sensor 92. The operations of the representative value storing portion 2, the rate-of-change calculating portion 3, the representative value updating portion 4, and the resetting portion 5 are as were explained in the Example.

The representative value acquiring portion 12 may acquire, from the representative value storing portion 2, the representative values (the maximum value Dx for the state quantity rate-of-change and the state quantity D at the time that the state quantity rate-of-change reached the maximum value Dx), on a regular periodic basis at periods T2 (for example, one week). Moreover, the threshold values Dt and Dxt, used by the first evaluating portion 15 and the second evaluating portion 16, may be set as appropriate in advance.

In the present example, when the alarm A has been outputted from the first evaluating portion 15, the operator considers the possibility that there has been a shift in the temperature sensor 92, and can decide to perform an inspection.

Moreover, when the alarm B has been outputted from the second evaluating portion 16, the operator considers the possibility that there may be a fault such as a performance breakdown in the heater 91, and can decide to perform an inspection.

The fault detecting systems explained in the above Example through Yet Still Another Further Example can be embodied through a computer that is provided with a CPU (Central Processing Unit), a memory device, and an interface, and a program for controlling these hardware resources. The CPU executes the processes explained in the Example through Yet Still Another Further Example, in accordance with a program that is stored in the memory device. Note that, as explained above, when the fault detecting system is decentralized into a plurality of devices, the CPU of each individual device may execute a process following a program that is stored in the storage device of that particular device.

The present invention can be applied to a technology for detecting a fault, or predicting a fault, in a sensor or actuator.

1: A fault detecting system comprising:
a data acquiring portion that acquires, as state quantities for process volumes, time series data of the state quantity;
a representative value storing portion that stores, as a representative value, a combination of the maximum value for a state quantity rate-of-change and the state quantity when the state quantity rate-of-change reached the maximum value;
a rate-of-change calculating portion that calculates a state quantity rate-of-change based on state quantity data acquired by the data acquiring portion;
a representative value updating portion that updates the representative values that are stored in the representative value storing portion to a combination of the most recent state quantity rate-of-change calculated by the rate-of-change calculating portion and the most recent state quantity acquired by the data acquiring portion, when the absolute value of the most recent state quantity rate-of-change calculated by the rate-of-change calculating portion is larger than the absolute value of the maximum value of the state quantity rate-of-change stored in the representative value storing portion; and
a resetting portion that resets, to a minimum value, the maximum value of the state quantity rate-of-change stored in the representative value storing portion, when a reset signal has been received from the outside.

2: The fault detecting system as set forth in claim 1, further comprising:
a data storing portion that stores temporarily data for the most recent state quantities in an amount that is specified in advance;
a transient state storing portion that stores, as transient state data relating to the representative values, state quantity data when a representative value has been updated by representative value updating portion; and
a transient state updating portion that updates, to the state quantity data stored in the data storing portion, the transient state data that is stored in the transient state data storing portion, when the representative value has been updated by the representative value updating portion.

3: The fault detecting system as set forth in claim 1, further comprising:
a related data acquiring portion that acquires, as related data, data of at least one process volume related to the process volume that is the subject of the data acquiring portion;
a related value storing portion that stores related data when a representative value has been updated by the representative value updating portion; and
a related value updating portion that updates, to related data obtained by the related data acquiring portion, the related data that is stored in the related data storing portion, when the representative value has been updated by the representative value updating portion.

4: The fault detecting system as set forth in claim 1, further comprising:
a representative value displaying portion that displays a representative value that is stored in the representative value storing portion; and
a reset operating portion that transmits the reset signal to the resetting portion in response to an operation from the outside.

5: The fault detecting system as set forth in claim 1, further comprising:
a representative value acquiring portion that acquires, at specific periods that are specified in advance, a representative value that is stored in the representative value storing portion;
a reset value transmitting portion that transmits the reset signal to the resetting portion after a representative value has been acquired by the representative value acquiring portion;
a representative value history storing portion that stores, in the order in which they were acquired, representative values acquired by the representative value acquiring portion;
a first evaluating portion that calculates an absolute value of a difference between a state quantity that is stored as a representative value in the representative value history storing portion and the most recent state quantity acquired as a representative value by the representative value acquiring portion, for each representative value that is stored in the representative value history storing portion when a representative value is acquired by the representative value acquiring portion, evaluates as a fault detection or as a state wherein a fault is predicted, and outputs a first alarm if at least one absolute value exceeds a first threshold value that has been specified in advance; and
a second evaluating portion that calculates an absolute value of a difference between a state quantity rate-of-change highest value that is stored as a representative value in the representative value history storing portion and the most recent state quantity rate-of-change highest value acquired as a representative value by the representative value acquiring portion, for each representative value that is stored in the representative value history storing portion when a representative value is acquired by the representative value acquiring portion, evaluates as a fault detection or as a state wherein a fault is predicted, and outputs a second alarm if at least one absolute value exceeds a second threshold value that has been specified in advance.

6: The fault detecting system as set forth in claim 1, wherein:
the process volume that is the subject of the data acquiring portion is a measured value of a temperature sensor within a heating device; and
the actuator that applies the state quantity change for the process volume that is the subject of the data acquiring portion is a heater of the heating device.

7: The fault detecting system as set forth in claim 1, wherein:
the process volume that is the subject of the data acquiring portion is a measured value of a pressure sensor within vacuum equipment; and
the actuator that applies the state quantity change for the process volume that is the subject of the data acquiring portion is a vacuum pump of the vacuum equipment.

8: The fault detecting system as set forth in claim 1, wherein:
the process volume that is the subject of the data acquiring portion is a measured value of a flow rate sensor within fluid transporting equipment; and
the actuator that applies the state quantity change for the process volume that is the subject of the data acquiring portion is a control valve of the fluid transporting equipment and a fluid transporting pressure generating device.

9: The fault detecting system as set forth in claim 1, wherein:
the process volume that is the subject of the data acquiring portion is a measured value of a supply air temperature sensor within an air-conditioning system; and
the actuator that applies the state quantity change for the process volume that is the subject of the data acquiring portion is a cooling/heating water flow rate controlling valve and a water feeding pump in the air-conditioning system.

10: The fault detecting system as set forth in claim 1, wherein:
the process volume that is the subject of the data acquiring portion is a measured value of a temperature sensor within a reaction furnace; and
the actuator that applies the state quantity change for the process volume that is the subject of the data acquiring portion is a heater of the reaction furnace.

11: A fault detecting method comprising:
a data acquiring step for acquiring, as state quantities for process volumes, time series data of the state quantity;
a rate-of-change calculating step for calculating a state quantity rate-of-change based on state quantity data acquired in the data acquiring step;
a representative value updating step for referencing a representative value storing portion that stores, as representative values, combinations of the state quantity rate-of-change highest values and state quantities when the state quantity rate-of-change highest values were reached, and for updating the representative values that are stored in the representative value storing portion to a combination of the most recent state quantity rate-of-change calculated in the rate-of-change calculating step and the most recent state quantity acquired in the data acquiring step, when the absolute value of the most recent state quantity rate-of-change calculated in the rate-of-change calculating step is larger than the absolute value of the maximum value of the state quantity rate-of-change stored in the representative value storing portion; and
a resetting step for resetting, to a minimum value, the maximum value of the state quantity rate-of-change stored in the representative value storing portion, when a reset signal has been received from the outside.

12: The fault detecting method as set forth in claim 11, further comprising:
a data storing step for storing temporarily data for the most recent state quantities in an amount that is specified in advance; and
a transient state updating step for updating, to the state quantity data stored in a data storing portion, transient state data that is stored in a transient state data storing portion as transient state data related to the representative value, when the representative value has been updated in the representative value updating step.

13: The fault detecting method as set forth in claim 11, further comprising:
a related data acquiring step for acquiring, as related data, data of at least one process volume related to the process volume that is a subject of the data acquiring step; and
a related value updating step for updating, to related data obtained in the related data acquiring step, the related data that is stored in a related data storing portion, when the representative value has been updated in the representative value updating step.

14: The fault detecting method as set forth in claim 11, further comprising:
a representative value displaying step for displaying a representative value that is stored in the representative value storing portion; and
a reset operating step for transmitting a reset signal in response to an operation from outside.

15: The fault detecting method as set forth in claim 11, further comprising:
a representative value acquiring step for acquiring, at specific periods that are specified in advance, a representative value that is stored in the representative value storing portion;
a reset value transmitting step for transmitting a reset signal after a representative value has been acquired in the representative value acquiring step;
a first evaluating step, for referencing a representative value history storing portion that stores, sequentially, representative values acquired in the representative value acquiring step, and for calculating an absolute value of a difference between a state quantity that is stored as a representative value in the representative value history storing portion and the most recent state quantity acquired as a representative value in the representative value acquiring step, for each representative value that is stored in the representative value history storing portion when a representative value is acquired in the representative value acquiring step, and for evaluating as a fault detection or as a state wherein a fault is predicted, and outputting a first alarm if at least one absolute value exceeds a first threshold value that has been specified in advance; and
a second evaluating step for calculating an absolute value of a difference between a state quantity rate-of-change highest value that is stored as a representative value in the representative value history storing portion and the most recent state quantity rate-of-change highest value acquired as a representative value in the representative value acquiring step, for each representative value that is stored in the representative value history storing portion when a representative value is acquired in the representative value acquiring step, and for evaluating as a fault detection or as a state wherein a fault is predicted, and outputting a second alarm if at least one absolute value exceeds a second threshold value that has been specified in advance.
